(19) United States
(12) Patent Application Publication
(10) Pub. No.: US 2025/0376764 A1
(43) Pub. Date: Dec. 11, 2025

(54) COMPOUND FOR FORMING MOLYBDENUM-CONTAINING THIN FILM, MOLYBDENUM-CONTAINING THIN FILM AND MANUFACTURING METHOD THEREOF

(71) Applicant: EGTM Co., Ltd., Suwon-si (KR)

(72) Inventors: Tae Young Lee, Suwon-si (KR); Woong Jin Choi, Suwon-si (KR); Sun Young Baik, Incheon (KR); Shin Beom Kim, Suwon-si (KR); Sung Jun Ji, Suwon-si (KR); Kun Hee Kim, Hwaseong-si (KR); Han Bin Lee, Yongin-si (KR)

(21) Appl. No.: 19/220,481

(22) Filed: May 28, 2025

(30) Foreign Application Priority Data
Jun. 10, 2024 (KR) 10-2024-0075060

(51) Int. Cl. C23C 16/455; C07F 11/00; C23C 16/02; C23C 16/40; C23C 16/44; C23C 16/46

(52) U.S. Cl. CPC C23C 16/45553; C07F 11/00; C23C 16/0227; C23C 16/405; C23C 16/4408; C23C 16/46

(57) ABSTRACT

A compound for forming a molybdenum-containing thin film according to an embodiment of the present disclosure is a compound represented by Chemical Formula 1, in which in Chemical Formula 1, R₁ and R₂ are each independently selected from hydrogen, a linear alkyl group having 1 to 6 carbon atoms, and a branched alkyl group having 3 to 6 carbon atoms, R₃ is selected from a linear alkyl group having 1 to 6 carbon atoms, a branched alkyl group having 3 to 6 carbon atoms, and an aryl group having 6 to 30 carbon atoms, and X is a halogen element. The compound according to an embodiment of the present disclosure has excellent thermal stability and volatility, and can be used as a precursor for forming a molybdenum-containing thin film, and can provide a high-quality molybdenum-containing thin film.

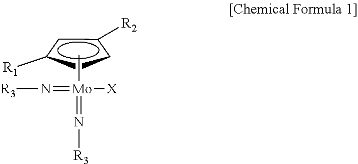

### CROSS-REFERENCE TO RELATED APPLICATIONS

This application claims the priority of Korean Patent Application No. 10⁻²⁰²⁴-0075060 filed on Jun. 10, 2024, in the Korean Intellectual Property Office, the disclosure of which is incorporated herein by reference.

### BACKGROUND

### Field

The present disclosure relates to a compound for forming a molybdenum-containing thin film, a molybdenum-containing thin film, and a manufacturing method thereof, and more particularly, to a compound for forming a molybdenum-containing thin film with improved thermal stability and volatility, a molybdenum-containing thin film, and a manufacturing method thereof.

### Description of the Related Art

Molybdenum-containing thin films, such as a molybdenum metal thin film, a molybdenum oxide thin film, a molybdenum nitride thin film, a molybdenum sulfide thin film, and a molybdenum carbide thin film, can be used as diffusion barriers for metal wiring, gate lines, electrodes, and the like in semiconductor processes, and have been used variously as hard coating materials, sensors, channel layers, and catalysts in industry.

Molybdenum has a high work function due to a high melting point, low coefficient of thermal expansion, high heat transferability, and low resistance value, and has excellent thermal/chemical stability. Therefore, the molybdenum may be used as an important metal material capable of suppressing the leakage current of capacitors that require high dielectric constants in highly integrated DRAMs. In addition, the molybdenum has low resistance and may be replaced with tungsten (W) metal that has been currently used in a 3D NAND flash memory, or used as a diffusion barrier of tungsten (W) metal. Furthermore, the molybdenum may also be used as a seed layer for growth of the molybdenum, and a diffusion barrier in a metal process in non-memory fields such as logic devices.

Meanwhile, in the memory and non-memory fields, the development of products with high aspect ratios and complex shapes of three-dimensional structures has been diversified, and a molybdenum-containing thin film suitable for such products has been required.

However, conventional molybdenum precursors having a biscyclopentadienyl group and an imido group have poor vaporization characteristics, making it difficult to be used in a deposition process. In addition, conventional molybdenum precursors having an alkylcyclopentadienyl group, a nitrile group, and a carbonyl group include carbonyl groups, which are highly toxic and thus have a problem of being difficult to be applied to high-temperature processes, and have a low vapor pressure, making it difficult to handle, and also have a difficulty in forming high-quality thin films.

### SUMMARY

Accordingly, an object of the present disclosure is to provide a precursor for forming a molybdenum-containing thin film, which has no process and performance problems for application to next-generation semiconductor products, etc., has advantages in a process due to improved thermal stability, high volatility, and high vapor pressure, and can increase a deposition rate, a molybdenum-containing thin film manufactured using the precursor, and a manufacturing method thereof.

The objects of the present disclosure are not limited to the aforementioned objects, and other objects, which are not mentioned above, will be apparent to those skilled in the art from the following description.

A compound for forming a molybdenum-containing thin film according to an embodiment of the present disclosure is a compound represented by Chemical Formula 1, in which in Chemical Formula 1, R₁ and R₂ are each independently selected from hydrogen, a linear alkyl group having 1 to 6 carbon atoms, and a branched alkyl group having 3 to 6 carbon atoms, R₃ is selected from a linear alkyl group having 1 to 6 carbon atoms, a branched alkyl group having 3 to 6 carbon atoms, and an aryl group having 6 to 30 carbon atoms, and X is a halogen element.

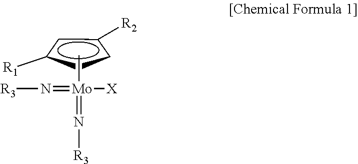

A molybdenum-containing thin film according to an embodiment of the present disclosure is manufactured by depositing the compound represented by Chemical Formula 1.

A manufacturing method of a molybdenum-containing thin film according to an embodiment of the present disclosure includes depositing the compound represented by Chemical Formula 1 on a substrate.

Details of other embodiments will be included in the detailed description of the invention and the accompanying drawings.

According to an embodiment of the present disclosure, the precursor for forming the molybdenum-containing thin film includes an alkyl cyclopentadienyl group and a halogen element, and has excellent structural stability and thermal stability of the compound and high volatility, thereby easily forming a high-quality thin film.

The effects according to the present disclosure are not limited by the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a 1H-NMR spectrum of a compound according to Example 1;

FIG. 2 is a 1H-NMR spectrum of a compound according to Example 2;

FIG. 3 is a 1H-NMR spectrum of a compound according to Comparative Example 1;

FIG. 4 is a TGA graph of a molybdenum precursor compound according to Example 1;

FIG. 5 is a DSC graph of a molybdenum precursor compound according to Example 1;

FIG. 6 is a TGA graph of a molybdenum precursor compound according to Example 2;

FIG. 7 is a DSC graph of a molybdenum precursor compound according to Example 2;

FIG. 8 is an XPS analysis result of a molybdenum oxide thin film formed under a substrate temperature of 260° C.;

FIG. 9 is an XPS analysis result of a molybdenum oxide thin film formed under a substrate temperature of 280° C.;

FIG. 10 is an XPS analysis result of a molybdenum oxide thin film formed under a substrate temperature of 300° C.;

FIG. 11 is an NMR spectrum measured before heat treatment of the compound according to Example 1 and after heat treatment at 150° C. and 180° C., respectively; and

FIG. 12 is an NMR spectrum measured before heat treatment of the compound according to Comparative Example 1 and after heat treatment at 150° C. and 180° C., respectively.

### DETAILED DESCRIPTION OF THE EMBODIMENT

Advantages and features of the present disclosure, and methods for accomplishing the same will be more clearly understood from exemplary embodiments to be described below in detail with reference to the accompanying drawings. However, the present disclosure is not limited to the following embodiments but may be implemented in various different forms. The embodiments are provided only to complete the disclosure of the present disclosure and to fully provide a person having ordinary skill in the art to which the present disclosure pertains with the category of the invention, and the present disclosure will be defined only by the appended claims.

In describing the present disclosure, a detailed description of related known technologies will be omitted if it is determined that they unnecessarily make the gist of the present disclosure unclear. The terms such as “including”, “having”, and “consisting of” used herein are generally intended to allow other components to be added unless the terms are used with the term “only”. When a component is expressed in a singular form, the singular form may include a plural form unless clearly stated otherwise.

Components are interpreted to include an ordinary error range even if not expressly stated.

A compound for forming a molybdenum-containing thin film according to an embodiment of the present disclosure may be represented by the following Chemical Formula 1. The compound represented by Chemical Formula 1 may be used as a precursor material for forming a molybdenum-containing thin film.

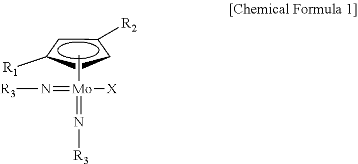

In Chemical Formula 1, R₁ and R₂ may be each independently selected from hydrogen, a linear alkyl group having 1 to 6 carbon atoms and a branched alkyl group having 3 to 6 carbon atoms.

In Chemical Formula 1, R₃ may be selected from a linear alkyl group having 1 to 6 carbon atoms, a branched alkyl group having 3 to 6 carbon atoms, and an aryl group having 6 to 30 carbon atoms.

In this case, since the vapor pressure property is excellent, the supply and deposition of the compound is easy during a thin film formation process, and a polymer thin film having a high deposition rate may be formed.

For example, in Chemical Formula 1, R₁ may be hydrogen, R₂ may be a linear alkyl group having 1 to 6 carbon atoms, and R₃ may be a branched alkyl group having 3 to 6 carbon atoms. In this case, since the vapor pressure property is excellent, the deposition process is easy, and the impurity content in the thin film is greatly reduced.

As another example, in Chemical Formula 1, R₁ and R₂ may be linear alkyl groups having 1 to 6 carbon atoms, and R₃ may be a branched alkyl group having 3 to 6 carbon atoms. At this time, R₁ and R₂ may be different from each other. In this case, since the vapor pressure property is excellent, the deposition process is easy, and the impurity content in the thin film is greatly reduced, thereby forming a high-quality molybdenum-containing thin film.

In Chemical Formula 1, X may be a halogen element. Specifically, for example, in Chemical Formula 1, X may be a halogen element such as chlorine, bromine, or iodine. Preferably, for example, X may be chlorine. The bonding of Mo and halogen elements has a higher bonding energy than the bonding of Mo and carbon elements. Therefore, when the compound of Chemical Formula 1 including the Mo-halogen element bond is used as a precursor for forming a molybdenum-containing thin film, a high-quality molybdenum-containing thin film with excellent thermal stability and almost no impurities may be formed.

Specifically, for example, the compound for forming the molybdenum-containing thin film may be a compound represented by the following Chemical Formula 2 or 3. In this case, the thermal stability and volatility are excellent. Therefore, the compound may be used as a precursor material for forming the molybdenum-containing thin film to easily form a high-quality molybdenum-containing thin film.

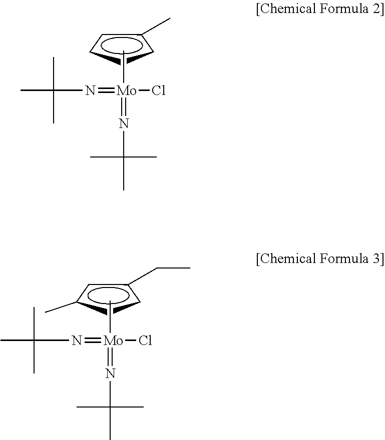

The molybdenum-containing thin film may be formed by depositing the compound for forming the molybdenum-containing thin film described above. Hereinafter, a method for manufacturing a molybdenum-containing thin film on a substrate using the compound described above will be described in detail.

For example, the molybdenum-containing thin film may be formed by depositing a compound on a substrate by any one method of plasma-enhanced chemical vapor deposition, thermal chemical vapor deposition, plasma-enhanced atomic layer deposition, and thermal atomic layer deposition.

Specifically, for example, the method for manufacturing the molybdenum-containing thin film includes a first step of cleaning and surface-treating a substrate, a second step of mounting the substrate in a chamber and heating the substrate, a third step of supplying a compound for forming the molybdenum-containing thin film represented by Chemical Formula 1 onto the substrate to form a single layer, a fourth step of supplying a reaction gas to the chamber to form a molybdenum thin film, and a fifth step of purging to remove an unreacted product.

The compound for forming the molybdenum-containing thin film represented by Chemical Formula 1 is the same as described above, and thus a duplicate description will be omitted.

First, the first step is a step of cleaning and surface-treating the substrate.

Before depositing the thin film, the substrate is cleaned to remove oil and water or foreign substances that may exist on the substrate. In addition, the substrate may be cleaned by selecting a dry or wet method, and both methods may also be used. For example, the cleaning may be performed using processes such as degreasing using an organic solvent, acid treatment, alkaline treatment, ultrasonic cleaning, and heat treatment, but is not limited thereto.

For example, a natural oxide film on the substrate surface may be removed using an etching solution such as hydrofluoric acid or sulfuric acid, or through other gaseous cleaning methods such as dry ice cleaning and UV ozone cleaning. In addition, in order to prevent the formation of the oxide film and facilitate the formation of the thin film, surface treatment may be performed to form a protective layer on the surface of the cleaned substrate.

Before mounting the cleaned and surface-treated substrate in the chamber, an inert gas may be purged inside the chamber to remove impurities. However, the present disclosure is not limited thereto. As such, a high-quality thin film may be formed by removing the impurities to suppress the generation of by-products due to side reactions. After removing impurities, the inside of the chamber may be maintained in a vacuum state for the reaction, but is not limited thereto.

The second step is a step of mounting the substrate in the chamber and heating the substrate. The heating temperature of the substrate in the second step may be 50° C. to 700° C. Preferably, the heating temperature of the substrate may be 250° C. to 400° C. or 250° C. to 350° C. In this case, the reaction may proceed quickly and smoothly, thereby forming a high-quality thin film.

The third step is a step of supplying the compound for forming the molybdenum-containing thin film represented by Chemical Formula 1 onto the substrate to form a single layer.

For example, the compound for forming the molybdenum-containing thin film may be supplied into the chamber by a bubbling method, but is not limited thereto. Optionally, the compound may be supplied together with a carrier gas as needed. The carrier gas may be used with gases that are not reactive with the compound and are lighter than the compound, so that the vaporized compound may be easily transferred to the reaction chamber. In addition, the reaction such as a growth rate of the thin film and the like may be easily controlled by controlling the flow rate of the compound to be supplied to the chamber. For example, the carrier gas may include one or more selected from argon (Ar), helium (He), and neon (Ne), but is not limited thereto.

The carrier gas may also be supplied into the chamber together with the compound by a bubbling method, but is not limited thereto.

As such, when the compound for forming the molybdenum-containing thin film is supplied onto the heated substrate, a single layer containing molybdenum is formed.

The fourth step is a step of forming the molybdenum thin film by supplying the reaction gas to the chamber.

The reaction gas reacts with the compound on the previously formed single layer to form a molybdenum-containing thin film. For example, the reaction gas may include at least one of O₂, O₃, H₂O, NO, NO₂, N₂O, H₂O₂, H₂, NH₃, alkylamine, hydrazine derivative, SiH₄, Si₂H₆, BH₃, B₂H₆, borane ammonia complex, GeH₄, and PH₃, but is not limited thereto.

For example, the molybdenum oxide thin film may be formed by supplying O₃ as the reaction gas, but is not limited thereto.

For example, the pressure inside the reactor may be maintained at 1×10⁻¹ Torr to 100×10⁻¹ Torr. Within this range, the reaction may proceed smoothly while ensuring the safety of the process.

The fifth step is a step of purging to remove the unreacted product. When a thin film with a desired thickness is formed, the inside of the chamber is purged to remove the unreacted product. For example, the chamber may be purged with inert gas such as argon (Ar), helium (He), and neon (Ne) to remove the unreacted product, but is not limited thereto.

Optionally, the method may further include a step of post-treating the thin film, if necessary. For example, the post-treating may be performed by any one method of an inductively coupled plasma (ICP) treatment process, a rapid thermal annealing (RTA) process, or a combination thereof, but is not limited thereto.

The method for manufacturing the molybdenum-containing thin film according to an embodiment of the present disclosure uses the compound represented by Chemical Formula 1 as a precursor, which has high thermal stability and excellent vapor pressure property. Accordingly, it is easy to control the supply and reactions of reactants in the deposition process, and a high-quality molybdenum-containing thin film with almost no impurities may be formed.

Therefore, the molybdenum-containing thin film may be used as wirings or electrodes of a semiconductor device, as well as electrodes or diffusion barriers of a memory device, thereby improving the performance of the device.

Hereinafter, the compound for forming the molybdenum-containing thin film according to the present disclosure and the molybdenum-containing thin film manufactured using the same will be described in more detail through the following Examples. However, these Examples are only presented to aid the understanding of the present disclosure, and the present disclosure is not limited to the following Examples.

### Example 1

11.5 g of sodium molybdate and 300 ml of dimethoxyethane (DME) were added to a flask. The mixture was stirred at −78° C., and slowly added and reacted with 9.6 g of t-butylamine, 22.5 g of triethylamine, and 55.1 g of chlorotrimethylsilane. After the reaction was completed, the solution was further refluxed for 16 hours. The mixture was filtered, and the solvent and volatiles were evaporated under vacuum to prepare a yellow solid reaction intermediate (tBuN)₂MoCl₂DME.

20 ml of an n-BuLi hexane solution (2.5 M) was slowly added dropwise and reacted to 4.1 g of methylcyclopentadiene (MeCp) in 200 ml of tetrahydrofuran at −78° C. After the reaction was completed, the mixture was slowly heated to room temperature, and further stirred at room temperature for 4 hours to prepare Li-MeCp. 300 ml of diethyl ether was added to a flask containing the reaction intermediate (tBuN)₂MoCl₂DME at −78° C. The entire amount of the prepared Li-MeCp solution was slowly added dropwise and reacted to the flask containing the reaction intermediate (tBuN)₂MoCl₂DME. After the reaction was completed, the mixture was heated to room temperature, and the reaction solution was stirred at room temperature overnight.

The mixture was filtered and depressurized to remove the solvent and by-products, and then distilled at a temperature of 130° C. and a pressure of 0.4 Torr to obtain 8.3 g (yield: 47%) of a solid-type compound (tBuN)₂(MeCp)MoCl of Chemical Formula 2.

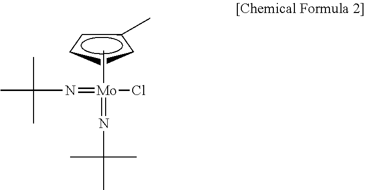

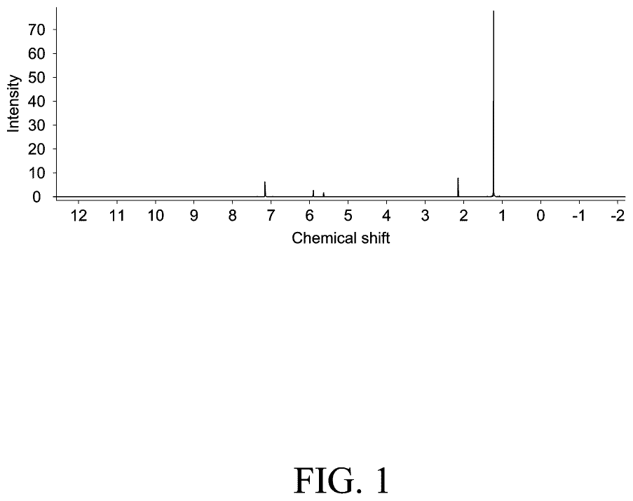

The obtained compound (tBuN)₂(MeCp)MoCl of Chemical Formula 2 was confirmed by 1H-NMR. The result thereof was illustrated in FIG. 1. FIG. 1 is a 1H-NMR spectrum of a compound according to Example 1.

¹H NMR (C6D6, 25° C.): 1.23(s, 18H), 2.15(s, 3H), 5.64(t, 2H), 5.91(t, 2H)

### Example 2

A yellow solid reaction intermediate (tBuN)₂MoCl₂DME was prepared in the same manner as in Example 1.

20 ml of an n-BuLi hexane solution (2.5 M) was slowly added dropwise and reacted to 5.3 g of ethylmethylcyclopentadiene (EtMeCp) in 200 ml of tetrahydrofuran at −78° C. After the reaction was completed, the mixture was slowly heated to room temperature, and further stirred at room temperature for 4 hours to prepare Li-EtMeCp.

300 ml of diethyl ether was added to a flask containing the reaction intermediate (tBuN)₂MoCl₂DME at −78° C. The entire amount of the prepared Li-EtMeCp solution was slowly added dropwise and reacted to the flask containing the reaction intermediate (tBuN)₂MoCl₂DME. After the reaction was completed, the mixture was heated to room temperature, and the reaction solution was stirred at room temperature overnight. The mixture was filtered and depressurized to remove the solvent and by-products, and then distilled at a temperature of 150° C. and a pressure of 0.4 Torr to obtain 5.7 g (yield: 30%) of a liquid-type compound (tBuN)₂(EtMeCp)MoCl of Chemical Formula 3.

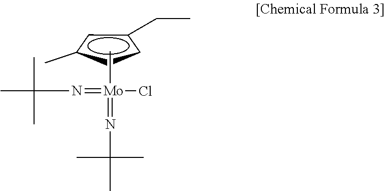

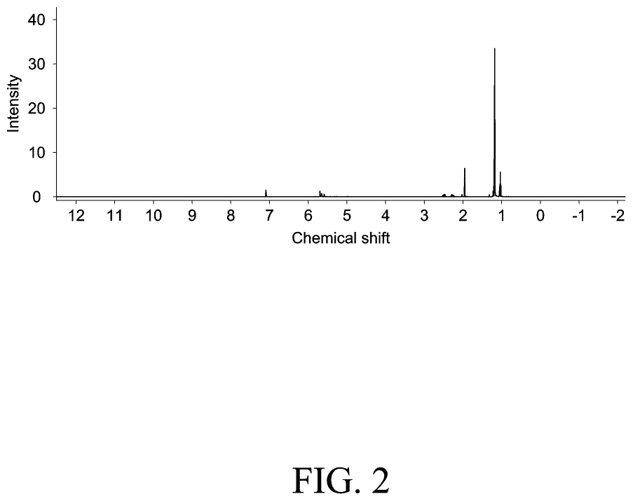

The obtained compound (tBuN)₂(EtMeCp)MoCl of Chemical Formula 3 was measured by 1H-NMR. The result thereof was illustrated in FIG. 2. FIG. 2 is a 1H-NMR spectrum of a compound according to Example 2.

¹H NMR (C6D6, 25° C.): 1.04(t, 3H), 1.18(d, 18H), 1.95(s, 3H), 2.27(m, 1H), 2.49(m, 1H), 5.59(t, 1H), 5.66(t, 1H), 5.70(t, 1H)

### Comparative Example 1

11.5 g of sodium molybdate and 300 ml of dimethoxyethane were added to a flask. The mixture was stirred at −78° C., and slowly added with 9.6 g of t-butylamine, 22.5 g of triethylamine, and 55.1 g of chlorotrimethylsilane. After the reaction was completed, the solution was further refluxed for 16 hours. The mixture was filtered and the solvent and volatiles were evaporated under vacuum to prepare a yellow solid-type reaction intermediate (tBuN)₂MoCl₂DME.

20 ml of an n-BuLi hexane solution (2.5 M) was slowly added dropwise and reacted to 3.2 g of cyclopentadiene in 200 ml of tetrahydrofuran at −78° C. After the reaction was completed, the mixture was slowly heated to room temperature, and further stirred at room temperature for 4 hours to prepare Li-Cp. 300 ml of diethyl ether was added to a flask containing the reaction intermediate (tBuN)₂MoCl₂DME at −78° C. In addition, the Li-Cp solution was slowly added dropwise and reacted to the flask containing the reaction intermediate (tBuN)₂MoCl₂DME. After the reaction was completed, the mixture was heated to room temperature, and the reaction solution was stirred at room temperature overnight. The mixture was filtered and depressurized to remove the solvent and by-products, and then distilled to obtain 5.1 g of a solid-type compound (tBuN)₂(Cp)MoCl of Chemical Formula 4.

300 ml of diethyl ether was added to a flask containing the reaction intermediate (tBuN)₂(Cp)MoCl at −78° C. 8.4 ml of a Li-Me diethyl ether solution (1.6 M) was slowly added dropwise thereto at −78° C., and then heated to room temperature, and the reaction solution was stirred at room temperature overnight. The mixture was filtered and depressurized to remove the solvent and by-products, and then distilled to obtain 1.7 g (yield: 35%) of a liquid-type compound (tBuN)₂(Cp)MoCH₃ of Chemical Formula 4.

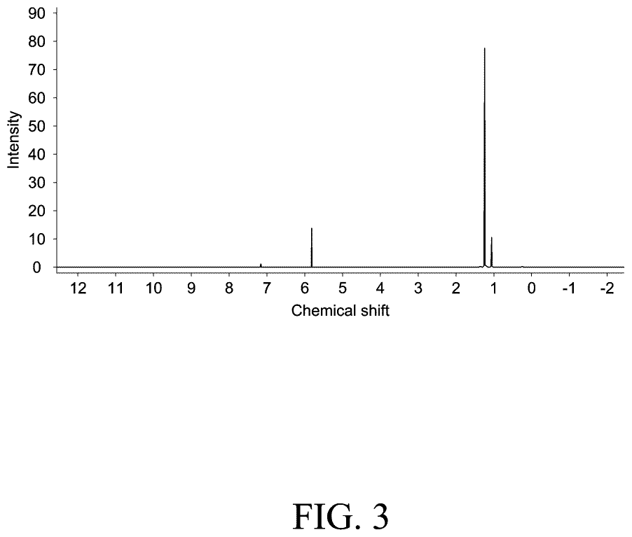

The obtained compound (tBuN)₂(Cp)MoCH₃ of Chemical Formula 4 was confirmed by 1H-NMR, and the result thereof was shown in FIG. 3. FIG. 3 is a 1H-NMR spectrum of a compound according to Comparative Example 1.

¹H NMR (C6D6, 25° C.): 1.05(s, 3H), 1.24(s, 18H), 5.82(s, 5H)

### Experimental Example 1

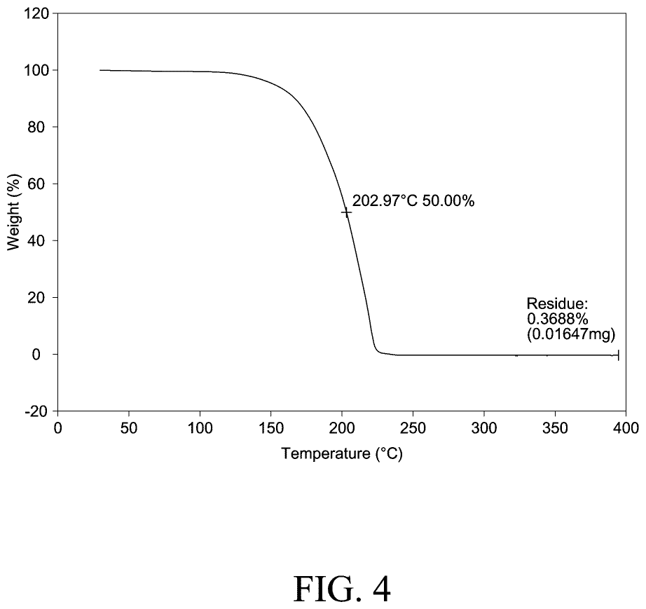

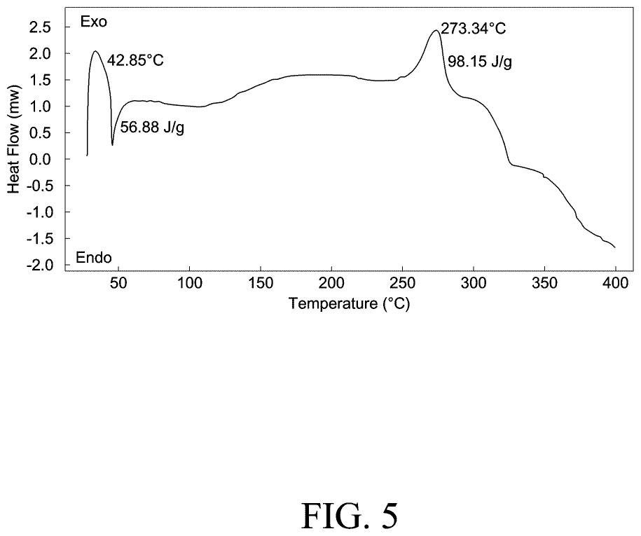

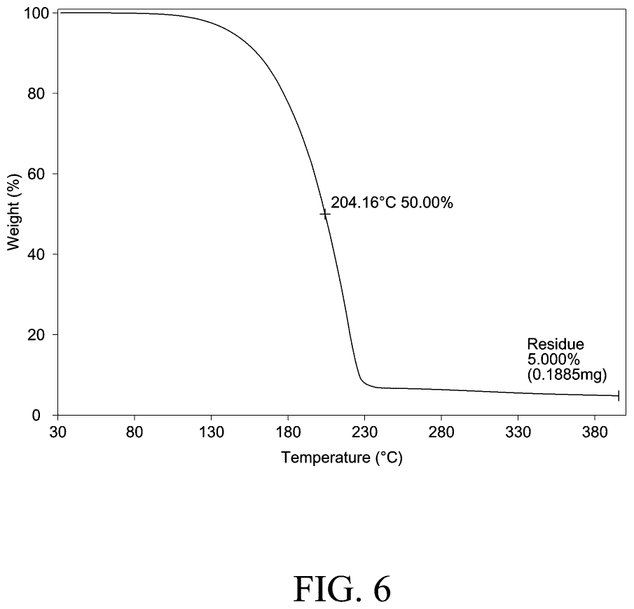

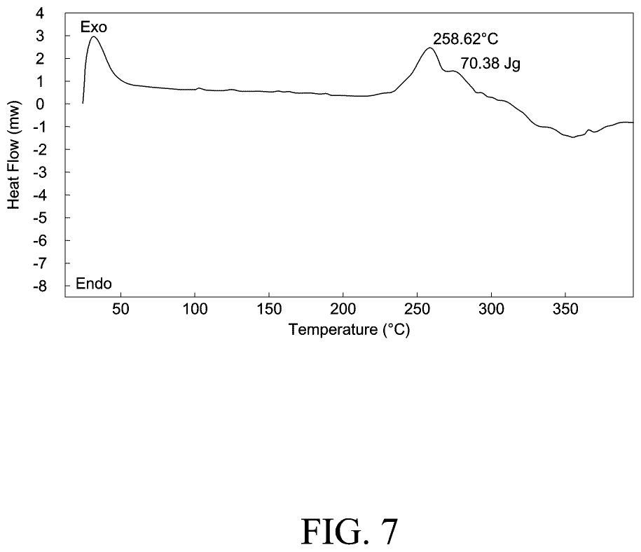

Thermogravimetric analysis (TGA) and differential scanning calorimetry (DSC) were performed on each of the compounds prepared according to Examples 1 and 2. The TGA was measured by injecting argon gas at a pressure of 1.5 bar/min while heating a sample to 400° C. at a rate of 10° C./min. The DSC was measured by heating the sample to 400° C. at a rate of 10° C./min. The results thereof were illustrated in FIGS. 4 to 7. FIG. 4 is a TGA graph of a molybdenum precursor compound according to Example 1, and FIG. 5 is a DSC graph of a molybdenum precursor compound according to Example 1. FIG. 6 is a TGA graph of a molybdenum precursor compound according to Example 2, and FIG. 7 is a DSC graph of a molybdenum precursor compound according to Example 2.

First, referring to FIGS. 4 and 6, it can be confirmed that both the compound of Chemical Formula 2 and the compound of Chemical Formula 3 have excellent vapor pressure properties with a half-life (T₅₀) of about 203° C. and about 204° C., respectively. Accordingly, it can be predicted that the supply and deposition of the precursor will be easy during the deposition process.

Next, referring to FIGS. 5 and 7, it can be confirmed that the compound of Chemical Formula 2 starts thermal decomposition at a temperature of about 230° C. or higher, and the compound of Chemical Formula 3 starts thermal decomposition at a temperature of about 250° C. or higher. Accordingly, it can be seen that the thermal stability of Chemical Formula 3 is relatively high.

### Experimental Example 2

The compound (tBuN)₂(MeCp)MoCl prepared according to Example 1 was used as a precursor to form a molybdenum oxide (MoO) thin film, which was analyzed by X-ray photoelectron spectroscopy (XPS). Specifically, the molybdenum oxide (MoO) thin film was formed using atomic layer deposition (ALD) in which a molybdenum precursor and a reaction gas were sequentially supplied. At this time, a silicon (Si) wafer was used as the substrate. During the deposition process, the substrate was heated to 200° C. and 220° C., respectively. In addition, a precursor compound contained in a stainless steel container was heated to a temperature of 110° C., and the temperature of a line through which the substrate passed was heated to 150° C. In addition, argon (Ar) gas with a flow rate of 100 sccm was used as a carrier gas, and the precursor compound was supplied to the reactor using a bubbler-type container. The internal pressure of the reactor was maintained at 1 torr. The precursor compound gas was supplied to the reactor for 3 seconds, and then argon gas was supplied at 1000 sccm for 15 seconds and then purged, and then ozone (O₃) gas, which was a reaction gas, was supplied at 600 sccm for 3 seconds, and then argon gas was again supplied at 1000 sccm for 15 seconds and then purged, which was 1 cycle, and such a cycle was repeated 100 times to form a molybdenum oxide (MoO) thin film.

The deposition results of the molybdenum oxide thin films formed under the conditions of substrate temperatures of 200° C., 220° C., 240° C., 260° C., 280° C., and 300° C. according to the process were shown in Table 1 below.

TABLE 1

| Deposition | | |
|---|---|---|
| temperature (° C.) | Thin film thickness (Å) | Growth rate (GPC) |
| 220 | 3.7 | 0.037 |
| 240 | 11.3 | 0.113 |
| 260 | 33 | 0.33 |
| 280 | 40.2 | 0.402 |
| 300 | 82 | 0.82 |

Referring to Table 1 above, it can be confirmed that as the substrate heating temperature increases during deposition, the thickness of the thin film becomes thicker and the growth rate of the thin film also tends to increase.

### Experimental Example 3

In the same manner as Experimental Example 2, the ALD method was used for deposition, but the process of supplying and purging only the molybdenum precursor compound gas was repeated to form a molybdenum-containing thin film. At this time, the substrate was heated to 260° C., 280° C., and 300° C. The thin film formed thus was analyzed by X-ray fluorescence spectrometry (XRF). The results thereof were shown in Table 2 below.

TABLE 2

| Temperature (° C.) | Intensity of Molybdenum |
|---|---|
| 260 | 0.0773 |
| 280 | 0.0536 |
| 300 | 0.0397 |

Referring to Table 2 above, it can be confirmed that an intensity difference of molybdenum is not large at each temperature of 260° C., 280° C., and 300° C., as a result of repeating the process of supplying and purging only the molybdenum precursor. From this, it can be seen that no thermal decomposition occurs in the temperature range of 260° C. to 300° C.

### Experimental Example 4

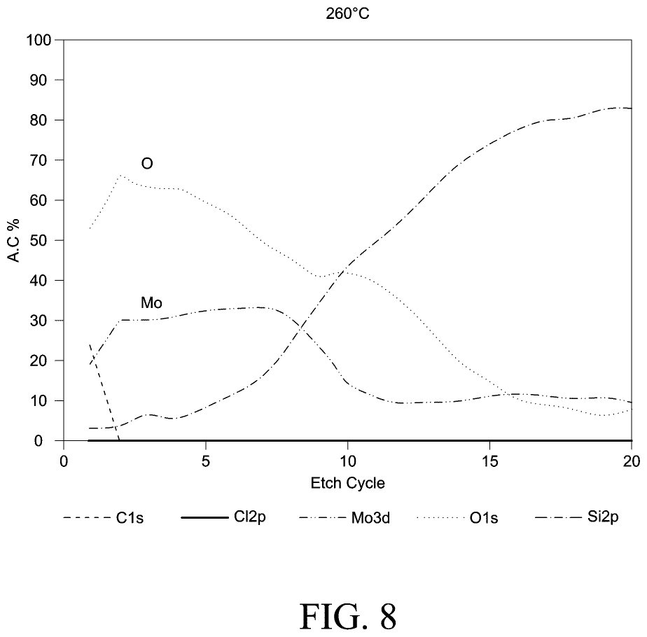

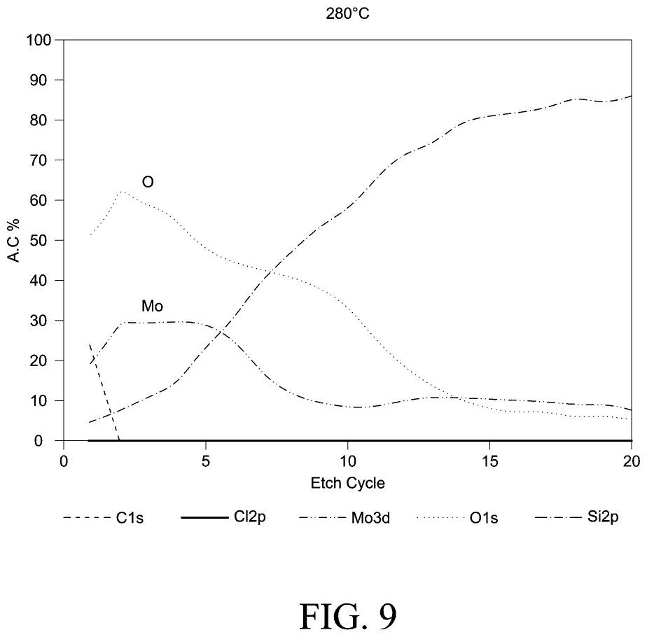

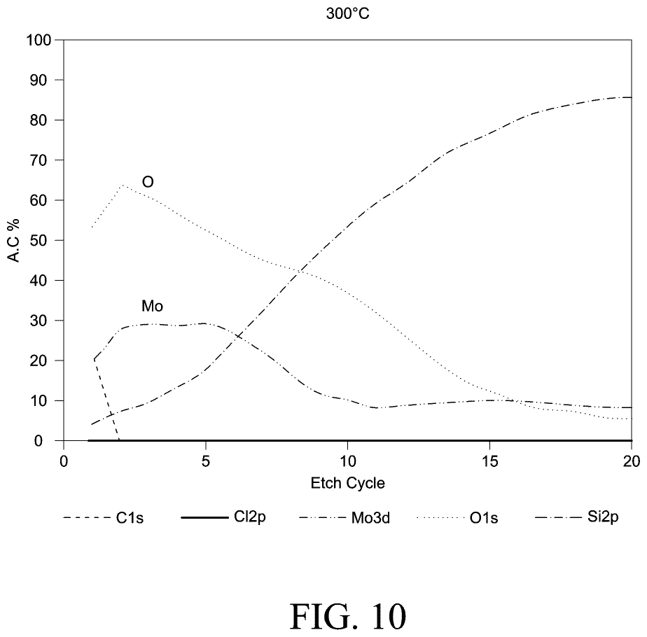

In the same manner as in Experimental Example 2, the substrate was heated to 260° C., 280° C., and 300° C. to form molybdenum oxide thin films, respectively. In order to determine the composition of the thin films formed as described above, the molybdenum oxide thin film was analyzed by X-ray photoelectron spectroscopy (XPS). The results thereof were illustrated in FIGS. 8 to 10. FIG. 8 is an XPS analysis result of a molybdenum oxide thin film formed under a substrate temperature of 260° C., FIG. 9 is an XPS analysis result of a molybdenum oxide thin film formed under a substrate temperature of 280° C., and FIG. 10 is an XPS analysis result of a molybdenum oxide thin film formed under a substrate temperature of 300° C.

Referring to FIGS. 8 to 10, it can be confirmed that chlorine impurities are not found regardless of temperature conditions, and carbon impurities are not found in the thin film except in a very early cycle. From this, it can be seen that when using the precursor compound according to the embodiment of the present disclosure, a thin film containing molybdenum oxide with an extremely low content of impurities such as chlorine or carbon can be formed even at low temperatures. Accordingly, it can be seen that the thin film containing molybdenum oxide can be variously used as an electrode, a diffusion barrier, etc., in devices such as DRAM and flash memory.

### Experimental Example 5

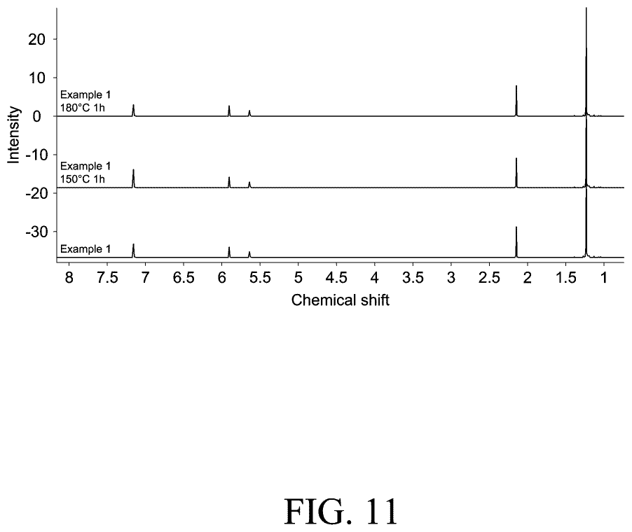

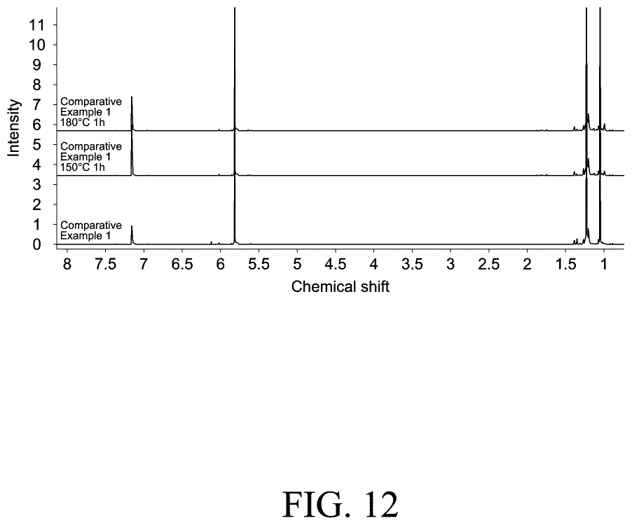

In order to compare the thermal stability of the compounds according to each of Example 1 and Comparative Example 1, 0.7 ml of the compound of Example 1 was added to each of two high-pressure reactors, and 0.7 ml of the compound of Comparative Example 1 was added to each of two other high-pressure reactors to prepare samples. One of the two samples of Example 1 and Comparative Example 1 was placed in a furnace heated to 150° C. and the other was placed in a furnace heated to 180° C., heated for 1 hour, and then cooled to room temperature. NMR analysis was performed on each sample cooled to room temperature. The resulting NMR spectra were shown in FIGS. 11 and 12. FIG. 11 is an NMR spectrum measured before heat treatment of the compound according to Example 1 and after heat treatment at 150° C. and 180° C., respectively, and FIG. 12 is an NMR spectrum measured before heat treatment of the compound according to Comparative Example 1 and after heat treatment at 150° C. and 180° C., respectively.

Referring to FIG. 11, it can be confirmed that in the case of the molybdenum precursor of Example 1, there is no change in NMR data even after heat treatment at 150° C. and 180° C.

Referring to FIG. 12, in the case of the molybdenum precursor of Comparative Example 1, it can be confirmed that there is a peak after heat treatment at 150° C. and 180° C. that is not shown in the NMR spectrum before heat treatment. The peak that is shown after heat treatment can be considered as a peak caused by impurities generated by thermal decomposition of the compound due to heat. Accordingly, in the case of the molybdenum precursor of Comparative Example 1, it can be seen that the thermal stability is lower than that of the compound of Example 1, and impurities are generated due to thermal decomposition.

From this, it can be seen that the compound of Example 1 exhibits high thermal stability by including an Mo—Cl bond having relatively high bond energy compared to the Mo—C bond included in the compound of Comparative Example 1.

A compound for forming a molybdenum-containing thin film, a molybdenum-containing thin film, and a manufacturing method thereof according to various embodiments of the present disclosure may be described as follows.

A compound for forming a molybdenum-containing thin film according to an embodiment of the present disclosure is a compound represented by the following Chemical Formula 1.

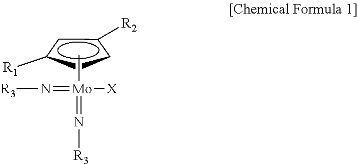

In Chemical Formula 1, R₁ and R₂ are each independently selected from hydrogen, a linear alkyl group having 1 to 6 carbon atoms, and a branched alkyl group having 3 to 6 carbon atoms, R₃ is selected from a linear alkyl group having 1 to 6 carbon atoms, a branched alkyl group having 3 to 6 carbon atoms, and an aryl group having 6 to 30 carbon atoms, and X is a halogen element.

According to another feature of the present disclosure, R₁ may be hydrogen, R₂ may be a linear alkyl group having 1 to 6 carbon atoms, and R₃ may be a branched alkyl group having 3 to 6 carbon atoms.

According to yet another feature of the present disclosure, R₁ and R₂ may be linear alkyl groups having 1 to 6 carbon atoms, R₃ may be a branched alkyl group having 3 to 6 carbon atoms, and R₁ and R₂ may be different from each other.

According to yet another feature of the present disclosure, the compound may be represented by the following Chemical Formula 2 or 3.

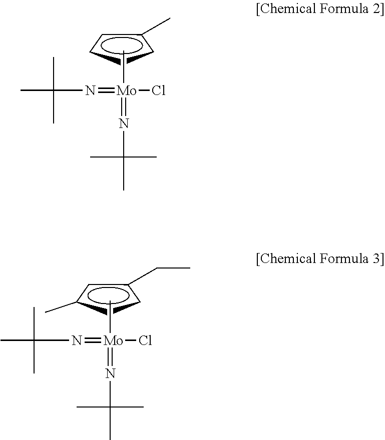

A molybdenum-containing thin film according to an embodiment of the present disclosure is manufactured by depositing the compound for forming the molybdenum-containing thin film.

A manufacturing method of a molybdenum-containing thin film according to an embodiment of the present disclosure includes depositing the compound for forming the molybdenum-containing thin film on a substrate.

According to yet another feature of the present disclosure, the deposition may be performed by any one of plasma-enhanced chemical vapor deposition, thermal chemical vapor deposition, plasma-enhanced atomic layer deposition, and thermal atomic layer deposition.

According to yet another feature of the present disclosure, the manufacturing method of the thin film may include a first step of cleaning and surface-treating a substrate; a second step of mounting the substrate in a chamber and heating the substrate; a third step of supplying a compound on the substrate to form a single layer; a fourth step of supplying a reaction gas to the chamber to form a molybdenum thin film; and a fifth step of purging to remove an unreacted product.

According to yet another feature of the present disclosure, the heating temperature of the substrate in the second step may be 50° C. to 700° C.

According to yet another feature of the present disclosure, the reaction gas may include at least one of O₂, O₃, H₂O, NO, NO₂, N₂O, H₂O₂, H₂, NH₃, alkylamine, hydrazine derivative, SiH₄, Si₂H₆, BH₃, B₂H₆, borane ammonia complex, GeH₄, and PH₃.

Although the embodiments of the present disclosure have been described in detail with reference to the accompanying drawings, the present disclosure is not limited thereto and may be embodied in many different forms without departing from the technical concept of the present disclosure. Accordingly, the various embodiments disclosed in the present disclosure are not intended to limit the technical spirit but describe the present disclosure and the technical spirit of the present disclosure is not limited by the following embodiments. Therefore, it should be understood that the above-described embodiments are illustrative in all aspects and do not limit the present disclosure. The protective scope of the present disclosure should be construed on the basis of the appended claims, and all the technical ideas in the equivalent scope thereof should be construed as falling within the scope of the present disclosure.

What is claimed is:

1. A compound for forming a molybdenum-containing thin film represented by the following Chemical Formula 1: 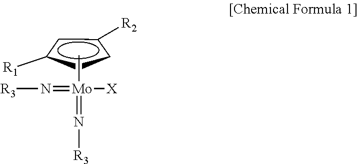
in Chemical Formula 1, R₁ and R₂ are each independently selected from hydrogen, a linear alkyl group having 1 to 6 carbon atoms, and a branched alkyl group having 3 to 6 carbon atoms, R₃ is selected from a linear alkyl group having 1 to 6 carbon atoms, a branched alkyl group having 3 to 6 carbon atoms, and an aryl group having 6 to 30 carbon atoms, and X is a halogen element.

2. The compound for forming the molybdenum-containing thin film of claim 1, wherein the R₁ is hydrogen, the R₂ is a linear alkyl group having 1 to 6 carbon atoms, and the R₃ is a branched alkyl group having 3 to 6 carbon atoms.

3. The compound for forming the molybdenum-containing thin film of claim 1, wherein the R₁ and R₂ are linear alkyl groups having 1 to 6 carbon atoms, the R₃ is a branched alkyl group having 3 to 6 carbon atoms, and the R₁ and R₂ are different from each other.

4. The compound for forming the molybdenum-containing thin film of claim 1, wherein the compound is represented by the following Chemical Formula 2 or 3:

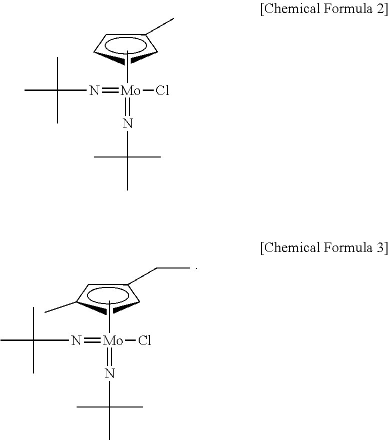

5. A molybdenum-containing thin film manufactured by depositing the compound according to claim 1.

6. A manufacturing method of a molybdenum-containing thin film comprising depositing the compound according to claim 1 on a substrate.

7. The manufacturing method of the molybdenum-containing thin film of claim 6, wherein the deposition is performed by any one of plasma-enhanced chemical vapor deposition, thermal chemical vapor deposition, plasma-enhanced atomic layer deposition, and thermal atomic layer deposition.

8. The manufacturing method of the molybdenum-containing thin film of claim 6, comprising:
a first step of cleaning and surface-treating the substrate;
a second step of mounting the substrate in a chamber and heating the substrate;
a third step of supplying the compound on the substrate to form a single layer;
a fourth step of supplying a reaction gas to the chamber to form a molybdenum thin film; and
a fifth step of purging to remove an unreacted product.

9. The manufacturing method of the molybdenum-containing thin film of claim 8, wherein the heating temperature of the substrate in the second step is 50° C. to 700° C.

10. The manufacturing method of the molybdenum-containing thin film of claim 8, wherein the reaction gas includes at least one of O₂, O₃, H₂O, NO, NO₂, N₂O, H₂O₂, H₂, NH₃, alkylamine, hydrazine derivative, SiH₄, Si₂H₆, BH₃, B₂H₆, borane ammonia complex, GeH₄, and PH₃.
